(19) United States
(12) Patent Application Publication
(10) Pub. No.: US 2022/0319816 A1
(43) Pub. Date: Oct. 6, 2022

(54) PLASMA ETCHING SYSTEM

(71) Applicant: JIANGSU LEUVEN INSTRUMENTS CO. LTD, Jiangsu (CN)

(72) Inventors: Haiyang LIU, Jiangsu (CN); Dongdong HU, Jiangsu (CN); Na LI, Jiangsu (CN); Xiaobo LIU, Jiangsu (CN); Shiran CHENG, Jiangsu (CN); Song GUO, Jiangsu (CN); Zhihao WU, Jiangsu (CN); Kaidong XU, Jiangsu (CN)

(73) Assignee: JIANGSU LEUVEN INSTRUMENTS CO. LTD, Jiangsu (CN)

(21) Appl. No.: 17/626,501

(22) PCT Filed: Feb. 26, 2020
(86) PCT No.: PCT/CN2020/076753

§ 371 Date: Jan. 12, 2022

(30) Foreign Application Priority Data
Aug. 21, 2019 (CN) 201910772838.5

(51) Int. Cl. H01J 37/32

(52) U.S. Cl. CPC H01J 37/32541; H01J 37/32568; H01J 37/32651; H01J 37/32183; H01J 37/3211; H01J 2237/334; H01J 2237/022

(57) ABSTRACT

Disclosed is a plasma etching system, comprising a reaction chamber, a base located in the reaction chamber and used for bearing a workpiece, and a dielectric window located on the reaction chamber. Flat plate type electrodes and coil electrodes are provided on the outer surface of the dielectric window; the flat plate type electrodes are located right over the base, and the coil electrodes are arranged in the peripheral regions of the flat plate type electrodes in a surrounding manner; a Faraday shielding layer is further provided between the coil electrodes and the outer surface of the dielectric window.

### TECHNICAL FIELD

The present application belongs to the technical field of semiconductor etching, and in particular, to a plasma etching system.

### DESCRIPTIOIN OF RELATED ART

In the semiconductor integrated circuit manufacturing process, etching is one of the most important processes. In the process of etching some non-volatile metal materials, plasma is accelerated under bias pressure to reach the surface of the metal material, and metal particles sputtered from the surface of the etched material adhere to all exposed surfaces within a reaction chamber, including an inner wall of the chamber and a dielectric window at the top of the chamber, causing contamination. In the prior art, a radio frequency electrode is usually a coil electrode, and an electric field formed by coil electrodes is mainly concentrated in a middle region, causing excessively fast etching in the middle part and more sputtered contaminants to be deposited in the middle region of the dielectric window.

In order to resolve the contamination problem, an electrostatic shielding member may be used. After a cleaning gas is injected into the reaction chamber, radio frequency power is loaded on the top to ionize the cleaning gas to remove contamination particles. Use of a Faraday shielding in a plasma processing system can reduce erosion of plasma to the material of the chamber. However, some plasma can still pass through slits between Faraday shielding units and contaminate the dielectric window. In addition, a long-time cleaning test shows that the foregoing solution provides a favorable cleaning effect for an outer edge region of the dielectric window, but a poor cleaning effect for the middle region.

### SUMMARY

To resolve the foregoing problem, the present invention provides a plasma etching system, which reduces contamination in a middle region of a dielectric window during etching, and can effectively clean the middle region of the dielectric window.

Technical solutions: The present invention provides a plasma etching system, including a reaction chamber, a base located in the reaction chamber and used for bearing a workpiece, and a dielectric window located on the reaction chamber, where: flat plate electrodes and coil electrodes are provided on an outer surface of the dielectric window; the flat plate electrodes are located right over the base; the coil electrodes are arranged in a peripheral region of the flat plate electrodes in a surrounding manner; and a Faraday shielding layer is further provided between the coil electrodes and the outer surface of the dielectric window.

Further, a size of the flat plate electrode is ½ to 1 of a size of the workpiece.

Further, the coil electrode is a vertical conical coil.

Further, the coil electrode consists of a plurality of coupled vertical conical coils.

Further, the system further includes a radio frequency power supply, a radio frequency matcher, and a radio frequency power distribution box; and radio frequency power of the radio frequency power supply is distributed and connected to the flat plate electrode and the coil electrode by the radio frequency power distribution box through the radio frequency matcher.

Further, the plasma etching system further includes a coil radio frequency power supply and a coil radio frequency matcher; and radio frequency power of the coil radio frequency power supply is connected to the coil electrode through the coil radio frequency matcher; and

the plasma etching system further includes a flat plate radio frequency power supply and a flat plate radio frequency matcher; and radio frequency power of the flat plate radio frequency power supply is connected to the flat plate electrode through the flat plate radio frequency matcher.

Beneficial effects: According to the present invention, the flat plate electrodes are provided at the center of the outer surface of the dielectric window and the coil electrodes are arranged in the peripheral regions of the flat plate type electrodes in a surrounding manner, so that contamination in the middle region of the dielectric window in the etching process is reduced and the etching uniformity is improved; moreover, the middle region of the dielectric window can be effectively cleaned by means of the flat plate electrodes.

### BRIEF DESCRIPTION OF THE DRAWINGS

FIG. 1 is a schematic structural diagram of an implementation of the present invention;

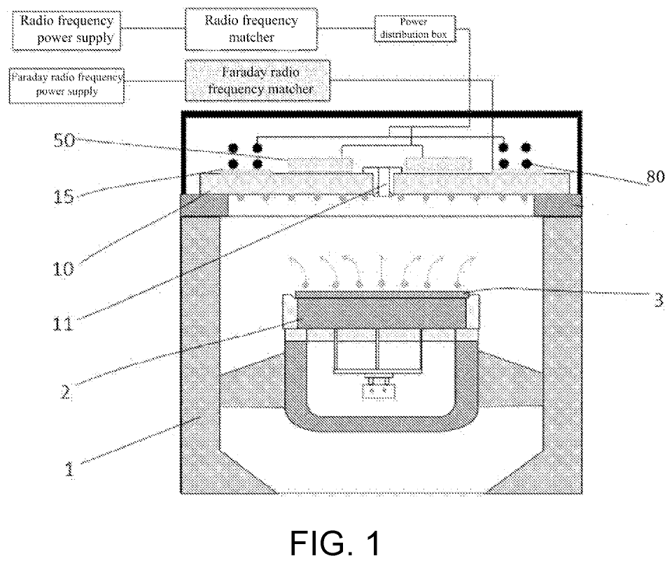

FIG. 2 is a schematic structural diagram of another implementation of the present invention; and

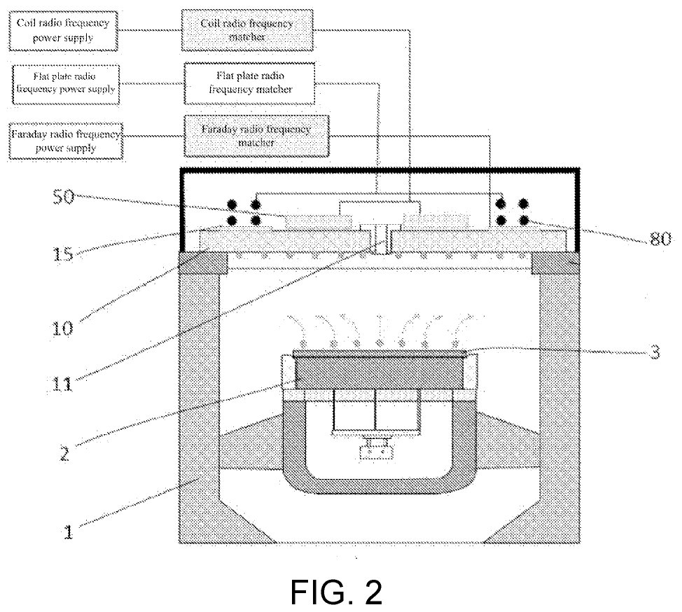

FIG. 3 is a flowchart of an application process of the present invention.

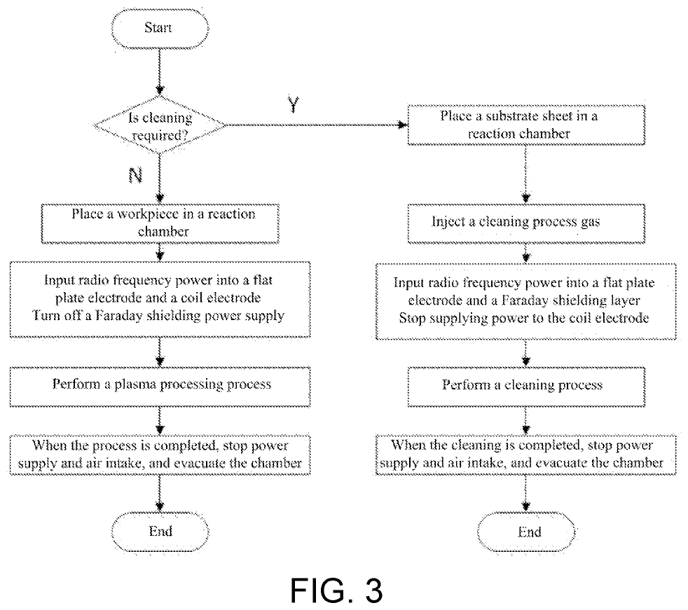

### DESCRIPTION OF THE EMBODIMENTS

The present invention is a plasma etching system, including a reaction chamber 1, a base 2 located in the reaction chamber 1 and used for bearing a workpiece 3, and a dielectric window 10 located on the reaction chamber 1. An air inlet nozzle 11 is mounted in the middle part of the dielectric window 10, to provide a process reaction gas for the reaction chamber 1.

Flat plate electrodes 50 and coil electrodes 80 are provided on an outer surface of the dielectric window 10. The flat plate electrodes 50 are located right over the base 2. The coil electrodes 80 are arranged in a peripheral region of the flat plate electrodes 50 in a surrounding manner. A Faraday shielding layer 15 is further provided between the coil electrodes 80 and the outer surface of the dielectric window 10.

The flat plate electrode 50 is used in the middle part of the dielectric window 10, and the flat plate electrode 50 has a lower inductive resistance than the coil electrode 80. Therefore, compared with an electrode of a coil structure, the flat plate electrode 50 generates an electric field of lower intensity during etching, which reduces an etching speed in the middle part to some extent, such that the etching speed in the middle part is close to an etching speed at edges, thereby making etching more uniform. In addition, the flat plate electrode 50 generates less sputtered contaminants deposited in the middle region of the dielectric window 10, and the flat plate electrode 50 generates a higher bias voltage than the electrode of the coil structure during etching, so that the sputtered contaminants on the dielectric window 10 are partially cleaned during the etching process, which reduces contamination in the middle region of the dielectric window during etching, thereby reducing difficulty and time costs for the subsequent cleaning process.

During the cleaning process, the flat plate electrode 50 generates a higher bias voltage on the dielectric window 10 directly below the flat plate electrode 50, which facilitates active plasma to bombard a lower surface of the dielectric window 10 directly below the flat plate electrode 50, to effectively clean the lower surface of the dielectric window 10, thereby reducing deposition of non-volatile metal particles on the top.

A size of the flat plate electrode 50 is ½ to 1 of a size of the workpiece. A maximum diameter of the flat plate electrode 50 should not be excessively large, otherwise the intensity of the electric field in the middle part is weakened to be lower than that of the electric field in the edge region, causing intensity of plasma excited in the middle part to weaken, thus reducing an etching rate.

The coil electrode 80 is a vertical conical coil. The conical coil can expand a coverage area of the coil electrode 80, and make the electric field uniformly distributed. If an inductive resistance of a single vertical conical coil is too low to meet a requirement of use, a plurality of vertical conical coils may be coupled to form the coil electrode 80.

In the present invention, radio frequency power may be supplied in either of the following two manners:

In a first manner, the present invention includes a radio frequency power supply, a radio frequency matcher, and a radio frequency power distribution box. Radio frequency power of the radio frequency power supply is distributed and connected to the flat plate electrode 50 and the coil electrode 80 by the radio frequency power distribution box through the radio frequency matcher. The power distribution box may distribute radio frequency power to the flat plate electrode 50 and the coil electrode 80 as required.

In a second manner, the plasma etching system further includes a coil radio frequency power supply and a coil radio frequency matcher. Radio frequency power of the coil radio frequency power supply is connected to the coil electrode 80 through the coil radio frequency matcher. The plasma etching system further includes a flat plate radio frequency power supply and a flat plate radio frequency matcher. Radio frequency power of the flat plate radio frequency power supply is connected to the flat plate electrode 50 through the flat plate radio frequency matcher.

The Faraday shielding layer 15 is also equipped with a Faraday radio frequency power supply and a Faraday radio frequency matcher.

When the etching process is performed in the reaction chamber 1, the flat plate electrode 50 and the coil electrode 80 are connected to the radio frequency power supply, the Faraday radio frequency power supply is turned off, and a process gas in the reaction chamber 1 is ionized to form plasma for etching. When the etching process ends, cleaning of the chamber starts, the radio frequency power of the coil electrode 80 is stopped, the radio frequency power is loaded to the Faraday shielding layer 15 and the flat plate electrode 50, and a cleaning gas is ionized in the upper part of the reaction chamber 1 to form active plasma, to completely clean the reaction chamber 1, especially an inner surface of the dielectric window 10.

1. A plasma etching system, comprising a reaction chamber, a base located in the reaction chamber and used for bearing a workpiece, and a dielectric window located on the reaction chamber, wherein flat plate electrodes and coil electrodes are provided on an outer surface of the dielectric window; the flat plate electrodes are located right over the base; the coil electrodes are arranged in a peripheral region of the flat plate electrodes in a surrounding manner; and a Faraday shielding layer is further provided between the coil electrodes and the outer surface of the dielectric window.

2. The plasma etching system according to claim 1, wherein a size of the flat plate electrode is ½ to 1 of a size of the workpiece.

3. The plasma etching system according to claim 1, wherein the coil electrode is a vertical conical coil.

4. The plasma etching system according to claim 3, wherein the coil electrode consists of a plurality of coupled vertical conical coils.

5. The plasma etching system according to claim 1, further comprising a radio frequency power supply, a radio frequency matcher, and a radio frequency power distribution box; and radio frequency power of the radio frequency power supply is distributed and connected to the flat plate electrode and the coil electrode by the radio frequency power distribution box through the radio frequency matcher.

6. The plasma etching system according to claim 1, wherein the plasma etching system further comprises a coil radio frequency power supply and a coil radio frequency matcher; and radio frequency power of the coil radio frequency power supply is connected to the coil electrode through the coil radio frequency matcher; and
the plasma etching system further comprises a flat plate radio frequency power supply and a flat plate radio frequency matcher; and radio frequency power of the flat plate radio frequency power supply is connected to the flat plate electrode through the flat plate radio frequency matcher.
